(19) United States
(12) Patent Application Publication
(10) Pub. No.: US 2026/0279449 A1
(43) Pub. Date: Sep. 17, 2026

(54) MEMORY, OPERATING METHOD THEREOF, AND MEMORY SYSTEM

(71) Applicant: YANGTZE MEMORY TECHNOLOGIES CO., LTD., Wuhan (CN)

(72) Inventors: Fan YANG, Wuhan (CN); Fengyuan XIE, Wuhan (CN); Ke LIANG, Wuhan (CN)

(21) Appl. No.: 19/288,822

(22) Filed: Aug. 1, 2025

(30) Foreign Application Priority Data
Mar. 14, 2025 (CN) 2025103086074

(51) Int. Cl. G11C 16/10; G11C 16/08; G11C 16/24; G11C 16/04; H10B 43/35

(52) U.S. Cl. CPC G11C 16/10; G11C 16/08; G11C 16/24; G11C 16/0483; H10B 43/35

(57) ABSTRACT

Examples of the present disclosure provides a memory, a memory system and an operating method for the memory. The memory includes a memory cell array and a peripheral circuit. The memory cell array includes a first memory cell coupled with a first bit line and a first word line. The peripheral circuit is coupled with the memory cell array and is configured to: provide a word-line programming voltage to the first word line and a bit-line programming voltage to the first bit line during a programming phase; discharge the first word line from the word-line programming voltage after the programming phase; and provide a charging voltage to the first bit line in the process of discharging the first word line from the word-line programming voltage.

### CROSS-REFERENCE TO RELATED APPLICATIONS

The present disclosure claims priority to Chinese Patent Application No. 2025103086074, which was filed March 14, 2025, and is hereby incorporated herein by reference in its entirety.

### TECHNICAL FIELD

The present disclosure relates to the field of semiconductor technology, and more particularly, to a memory, a memory system, and an operating method for the memory.

### BACKGROUND

The memory may comprise a semiconductor device and may comprise a non-volatile memory that retains stored data even after power loss. For example, non-volatile memory may be widely used in systems of computers, cellphones, smartphones, personal digital assistants, and other electronic devices.

### SUMMARY

According to a first aspect, an example of the present disclosure provides a memory. The memory comprises a memory cell array and a peripheral circuit. The memory cell array comprises a first memory cell, wherein the first memory cell is coupled with a first bit line and a first word line. The peripheral circuit is coupled with the memory cell array and is configured to: provide a word-line programming voltage to the first word line and a bit-line programming voltage to the first bit line during a programming phase; discharge the first word line from the word-line programming voltage after the programming phase; and provide a charging voltage to the first bit line in the process of discharging the first word line from the word-line programming voltage.

In an example, the peripheral circuit is further configured to: discharge the first word line from the word-line programming voltage from a first point of time; and provide the charging voltage to the first bit line from the first point of time.

In an example, the memory cell array further comprises a second memory cell coupled with a second bit line and the first word line; wherein the peripheral circuit is further configured to: provide a bit-line inhibit voltage to the second bit line during the programming phase, wherein the bit-line inhibit voltage is greater than the bit-line programming voltage; and control the second bit line to be in a floating state after the programming phase.

In an example, the memory cell array further comprises a plurality of third memory cells coupled with a plurality of third bit lines and the first word line, wherein the peripheral circuit is further configured to: provide a plurality of bit-line intermediate voltages to the plurality of third bit lines during the programming phase, wherein the plurality of bit-line intermediate voltages are greater than the bit-line programming voltage and less than the bit-line inhibit voltage, and the plurality of bit-line intermediate voltages are different from each other; and provide the charging voltage to a first set of third bit lines among the plurality of third bit lines and control a second set of third bit lines among the plurality of third bit lines to be in the floating state after the programming phase, wherein the bit-line intermediate voltages provided to the first set of third bit lines are less than a preset threshold, and the bit-line intermediate voltages provided to the second set of third bit lines are greater than the preset threshold.

In an example, the first bit line, the second bit line, and the third bit lines are respectively coupled with a power supply terminal through a plurality of clamp transistors, and the peripheral circuit is further configured to: in the process of providing the charging voltage to the first bit line, provide a bias voltage to control terminals of the plurality of clamp transistors, so that the clamp transistors among the plurality of clamp transistors coupled with the first bit line and the first set of third bit lines are in a turn-on state, and the clamp transistors among the plurality of clamp transistors coupled with the second bit line and the second set of third bit lines are in a turn-off state.

In an example, the clamp transistors comprise a NMOS transistor.

In an example, a voltage value of the bias voltage is a sum of the preset threshold and a threshold voltage of the clamp transistors.

In an example, the peripheral circuit is further configured to: discharge the first word line from the word-line programming voltage in steps.

In an example, at respective steps in the process of discharging the first word line, rise rates of a voltage of the first bit line differ from each other, and fall rates of a voltage of the second bit line differ from each other.

In an example, the memory cell array further comprises a plurality of second word lines, and the peripheral circuit is further configured to: provide a pass voltage to the second word lines during the programming phase; and discharge the second word lines from the pass voltage after the programming phase, wherein the pass voltage is less than the word-line programming voltage.

In an example, the bit-line programming voltage comprises a ground voltage.

According to a second aspect, an example of the present disclosure provides a memory system. The memory system comprises the memory as mentioned in any of the above examples and a controller. The controller is coupled with the memory and is configured to control the memory.

According to a third aspect, an example of the present disclosure provides an operating method for a memory. The memory comprises a first memory cell coupled with a first bit line and a first word line. The operating method for the memory comprises: providing a word-line programming voltage to the first word line and a bit-line programming voltage to the first bit line during a programming phase; discharging the first word line from the word-line programming voltage after the programming phase; and providing a charging voltage to the first bit line in the process of discharging the first word line from the word-line programming voltage.

In an example, discharging the first word line from the word-line programming voltage comprises: discharging the first word line from the word-line programming voltage from a first point of time, and providing the charging voltage to the first bit line comprises: providing the charging voltage to the first bit line from the first point of time.

In an example, the memory further comprises a second memory cell coupled with a second bit line and the first word line, and the operating method further comprises: providing a bit-line inhibit voltage to the second bit line during the programming phase, wherein the bit-line inhibit voltage is greater than the bit-line programming voltage; and controlling the second bit line to be in a floating state after the programming phase.

In an example, the memory further comprises a plurality of third memory cells coupled with a plurality of third bit lines and the first word line, and the operating method further comprises: providing a plurality of bit-line intermediate voltages to the plurality of third bit lines during the programming phase, wherein the plurality of bit-line intermediate voltages are greater than the bit-line programming voltage and less than the bit-line inhibit voltage, and the plurality of bit-line intermediate voltages are different from each other; and providing the charging voltage to a first set of third bit lines among the plurality of third bit lines and controlling a second set of third bit lines among the plurality of third bit lines to be in the floating state after the programming phase, wherein the bit-line intermediate voltages provided to the first set of third bit lines are less than a preset threshold, and the bit-line intermediate voltages provided to the second set of third bit lines are greater than the preset threshold.

In an example, the first bit line, the second bit line, and the third bit lines are respectively coupled with a power supply terminal through a plurality of clamp transistors, and the operating method further comprises: in the process of providing the charging voltage to the first bit line, providing a bias voltage to control terminals of the plurality of clamp transistors, so that the clamp transistors among the plurality of clamp transistors coupled with the first bit line and the first set of third bit lines are in a turn-on state, and the clamp transistors among the plurality of clamp transistors coupled with the second bit line and the second set of third bit lines are in a turn-off state.

In an example, the clamp transistors comprise a NMOS transistor.

In an example, a voltage value of the bias voltage is a sum of the preset threshold and a threshold voltage of the clamp transistors.

In an example, discharging the first word line from the word-line programming voltage comprises: discharging the first word line from the word-line programming voltage in steps.

In an example, at respective steps in the process of discharging the first word line, rise rates of a voltage of the first bit line differ from each other, and fall rates of a voltage of the second bit line differ from each other.

In an example, the memory further comprises a plurality of second word lines, and the operating method further comprises: providing a pass voltage to the second word lines during the programming phase; and discharging the second word lines from the pass voltage after the programming phase, wherein the pass voltage is less than the word-line programming voltage.

In an example, the bit-line programming voltage comprises a ground voltage.

### BRIEF DESCRIPTION OF THE DRAWINGS

Other features, objects, and advantages of the present disclosure will become more apparent upon reading the detailed description of non-limiting examples made with reference to the following drawings, wherein:

FIG. 1 is a schematic block diagram of a system having a memory system provided by an example of the present disclosure;

FIG. 2A and FIG. 2B are schematic block diagrams of a memory system provided by an example of the present disclosure;

FIG. 3 is a schematic block diagram of a memory provided by an example of the present disclosure;

FIG. 4 is a schematic circuit diagram of a memory cell array provided by an example of the present disclosure;

FIG. 5 is a schematic diagram of a structure comprising a memory cell string provided by an example of the present disclosure;

FIG. 6 is a schematic waveform diagram of a selected word line, a selected bit line, an unselected word line, and an unselected bit line in a programming phase and a discharging phase provided by an example of the present disclosure;

FIG. 7A is a schematic structural diagram of a peripheral circuit coupled with a bit line provided by an example of the present disclosure;

FIG. 7B is an equivalent circuit diagram of the bit line and the peripheral circuit coupled with the bit line shown in FIG. 7A;

FIG. 8 is a schematic waveform diagram in a programming phase and a discharging phase including a first word line and a first bit line provided by an example of the present disclosure;

FIG. 9 is a schematic diagram of a distribution of threshold voltages of a first memory cell, a second memory cell, and a third memory cell provided by an example of the present disclosure;

FIG. 10 is a partial circuit diagram of a page buffer provided by an example of the present disclosure; and

FIG. 11 is a schematic flowchart of an operating method for a memory provided by an example of the present disclosure.

### DETAILED DESCRIPTION

In order to better understand the present disclosure, various aspects of the present disclosure will be described in more detail with reference to the accompanying drawings. It should be understood that these detailed descriptions are merely descriptions of examples of the present disclosure, and are not intended to limit the scope of the present disclosure in any manner. Throughout the description, like reference numbers refer to like elements. The expression “at least one of … or …” comprises any and all combinations of one or more of the associated listed items

It should be noted that in this specification, the expressions of the first, second, third, etc., are merely used to distinguish one feature from another feature, and do not represent any limitation on the features, and in particular, do not represent any order. Thus, a first memory cell discussed in the present disclosure may also be referred to as a second memory cell, or vice versa, without departing from the teachings of the present disclosure.

In the drawings, thickness, size, and shape of components have been slightly adjusted for ease of illustration. The drawings are merely examples and are not drawn to scale. As used herein, the terms “substantially,” “about,” and the like are used as the terms that represent approximation, and are not used as terms that represent the extent, and are intended to illustrate inherent deviations in measured values or calculated values to be recognized by those of ordinary skill in the art.

It should also be understood that expressions such as at least one of “comprising,” “comprise,” “having,” “including,” or “include,” and the like, are open and not closed expressions in this specification that indicate the presence of at least one of stated features, elements, or components, but do not preclude the presence of at least one of one or more other features, elements, components, or combinations thereof. Furthermore, when expressions such as “at least one of” appear before the list of listed features, it embellishes the entire list of features rather than just embellishing individual elements in the list. In addition, when describing examples of the present disclosure, “may” is used to mean “one or more examples of the present disclosure”. Also, the term “exemplarily” is intended to refer to an example or illustration.

Unless otherwise defined, all wording (comprising engineering terms and scientific and technological terms) used herein have the same meaning as commonly understood by those of ordinary skill in the art to which the present disclosure belongs. It should also be understood that unless explicitly stated in the present disclosure, words defined in a common dictionary should be interpreted as having a meaning that is consistent with their meaning in the context of the related art, and should not be interpreted in an idealized or overly formal sense.

It should be noted that, in the case of no conflict, examples and features in the examples of the present disclosure may be combined with each other. In addition, unless expressly defined or contradicted with context, the specific operations comprised in the methods described in the present disclosure need not be limited to the recited order, but may be performed in any order or in parallel.

Hereinafter, the present disclosure will be described in detail with reference to the accompanying drawings and in combination with the examples.

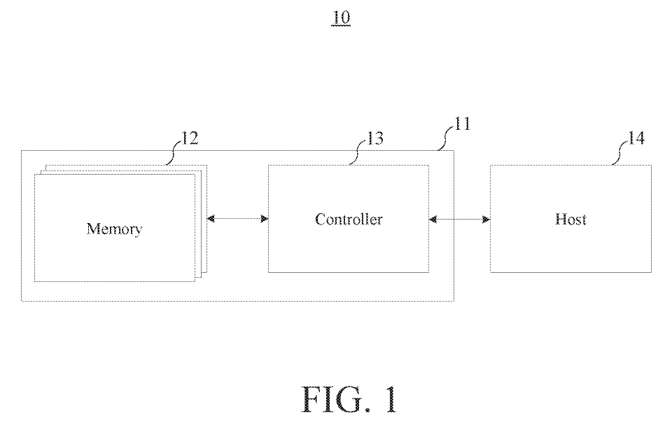

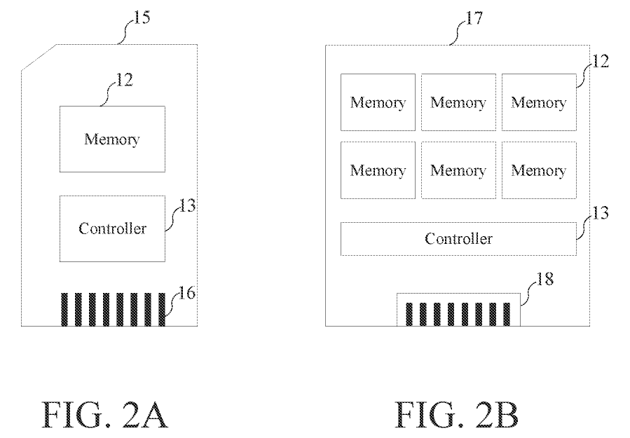

FIG. 1 shows a schematic block diagram of a system having a memory system provided by an example of the present disclosure. FIG. 2A and FIG. 2B show schematic block diagrams of a memory system provided by an example of the present disclosure.

As shown in FIG. 1, the system 10 may comprise a mobile phone, a desktop computer, a laptop computer, a tablet computer, an on-board computer, a game console, a printer, a positioning device, a wearable electronic device, a smart sensor, a virtual reality (VR) device, an augmented reality (AR) device, or any other suitable electronic device having a memory system 11 located therein. The system 10 may comprise a host 14 and a memory system 11, which may comprise one or more memories 12 and a controller 13. The host 14 may comprise a processor of an electronic device, such as a central processing unit (CPU), or may comprise a system-on-chip (SoC), such as an application processor (AP). The host 14 may be configured to send or receive data to and from the memory 12.

The memory 12 may comprise the memory mentioned in any of the examples of the present disclosure. The controller 13 is coupled to the memory 12 and the host 14 and is configured to control the memory 12. The controller 13 may manage data stored in the memory 12 and communicate with the host 14. In some examples, the controller 13 is designed to operate in a low duty cycle environment, such as a secure digital (SD) card, compact flash (CF) card, universal serial bus (USB) flash drive, or other medium used in electronic devices such as personal computers, digital cameras, mobile phones, and the like. In other examples, the controller 13 is designed to operate in a high duty cycle environment, such as an SSD (solid state disk) or embedded multi-media-card (eMMC) functioning as a data storage for a mobile device, such as a smart phone, tablet, laptop, and the like, and an enterprise storage array. The controller 13 may be configured to control operations of the memory 12, such as read, erase, and program operations. The controller 13 may also be configured to manage various functions related to data stored in the memory 12 or to be stored in the memory 12, comprising, but not limited to, bad block management, garbage collection, logical-to-physical address translation, wear leveling, and the like. In some examples, the controller 13 is further configured to process error correction code (ECC) related to data read from or programmed to the memory 12. Other suitable functions may also be performed by the controller 13, such as formatting the memory 12. The controller 13 may communicate with an external device (e.g., host 14) according to a particular communication protocol. For example, the controller 13 may communicate with external devices through at least one of a variety of interface protocols, such as a USB protocol, an MMC protocol, a Peripheral Component Interconnect (PCI) protocol, a PCI-express (PCI-E) protocol, an Advanced Technology Attachment (ATA) protocol, a serial ATA protocol, a parallel ATA protocol, a Small Computer Small Interface (SCSI) protocol, an Enhanced Small Disk Interface (ESDI) protocol, an Integrated Drive Electronics (IDE) protocol, a Firewire protocol, and the like.

The controller 13 and the one or more memories 12 may be integrated into various types of memory systems, e.g., comprised in the same package, such as a Universal Flash Storage (UFS) package or an eMMC package. For example, the memory system 11 may be implemented and packaged into different types of final electronic products. In one example as shown in FIG. 2A, the controller 13 and the single memory 12 may be integrated into a memory card 15. The memory card 15 may comprise a PC Card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), UFS, and the like. The memory card 15 may further comprise a memory card connector 16 that couples the memory card 15 with a host (e.g., the host 14 in FIG. 1). In another example as shown in FIG. 2B, the controller 13 and the multiple memories 12 may be integrated into an SSD 17. The SSD 17 may further comprise an SSD connector 18 coupling SSD 17 with a host (e.g., host 14 in FIG. 1). In some examples, at least one of the storage capacity or operating speed of SSD 17 is higher than that of the memory card 15.

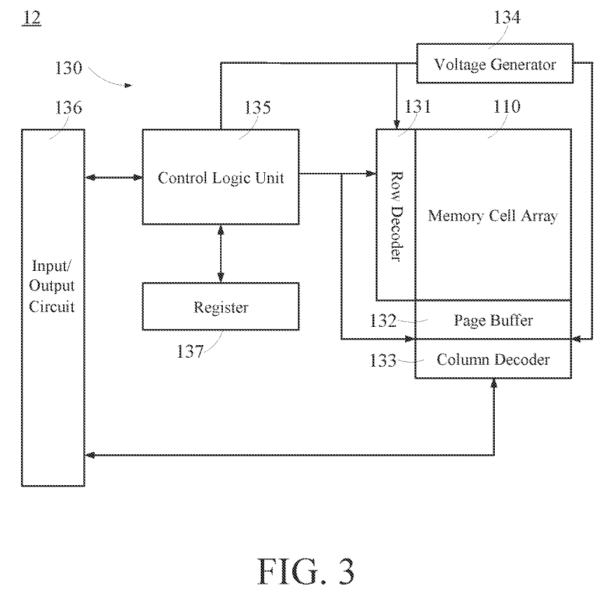

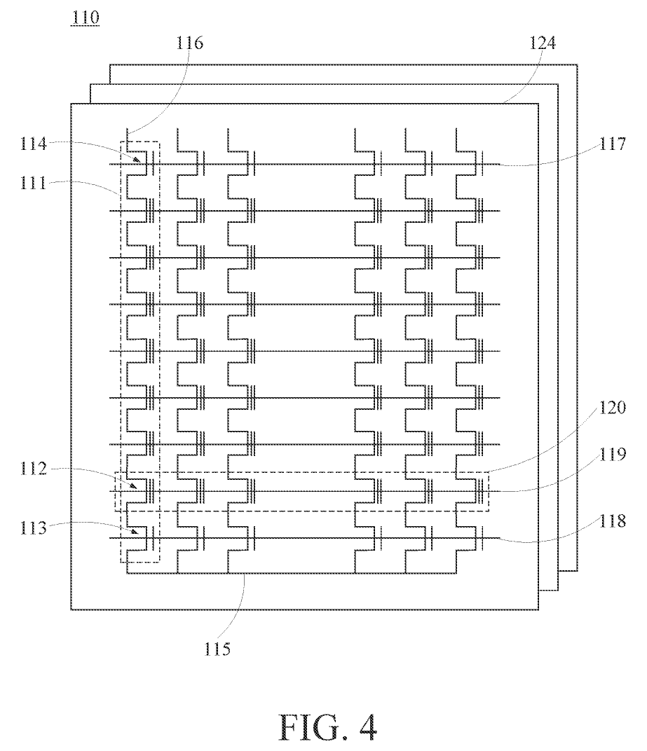

FIG. 3 shows a schematic block diagram of a memory provided by an example of the present disclosure. FIG. 4 shows a schematic circuit diagram of a memory cell array provided by an example of the present disclosure.

As shown in FIG. 3, the memory 12 may comprise a memory cell array 110 and a peripheral circuit 130 coupled to the memory cell array 110. For example, the memory cell array 110 may comprise an array of NAND flash memory cells. As shown in FIG. 4, a memory cell 112 is provided in a memory cell string 111. The memory cell string 111 may comprise a plurality of memory cells 112 coupled in series. The memory cell 112 may comprise a memory cell comprising a floating gate type transistor, or a memory cell comprising a charge trap type transistor.

In some examples, the memory cell 112 may be a single-level cell (SLC) having two possible states and may store one bit of data. In some other examples, the memory cell 112 may be a multi-level memory cell xLC having more than two possible states and may store more than one bit of data. For example, a multi-level cell (MLC) may have four possible states and may store two bits of data; a triple-level cell (TLC) may have eight possible states and may store three bits of data; and a quad-level cell (QLC) may have sixteen possible states and may store four bits of data. In general, multi-level cell xLC may have 2ⁿ possible states and may store n bits of data, wherein n is an integer, e.g., n is equal to 2, 3, and 4 for MLC, TLC, and QLC, respectively.

In some examples, as shown in FIG. 4, the memory cell string 111 may further comprise a source selective gate (SSG) transistor 113 at its one end (e.g., source end), and a drain selective gate (DSG) transistor 114 at its other end (e.g., drain end). The SSG transistor 113 and the DSG transistor 114 may be configured to activate the selected memory cell string 111 during read and program operations.

In some examples, the memory cell strings 111 may be organized into a plurality of memory blocks 124. Sources of the memory cell strings 111 in the same memory block 124 may be coupled through a same source line (SL) 115. In other words, all memory cell strings 111 in the same memory block 124 may have an array common source (ACS).

In some examples, the drain of each memory cell string 111 may be coupled to a respective bit line 116, and data may read or written (programmed) from the bit line 116 via an output bus (not shown). The plurality of memory cell strings 111 arranged in columns may be coupled to different bit lines 116, respectively.

In some examples, each memory cell string 111 may be configured to at least one of apply a select voltage or a deselect voltage to the gate of the respective DSG transistor 114 through the DSG line 117, or apply a select voltage or a deselect voltage to the gate of the respective SSG transistor 113 through the SSG line 118. The memory cell string 111 may thus become a selected memory cell string or an unselected memory cell string.

In some examples, memory cells 112 in the same layer in different memory cell strings 111 may be coupled by word lines 119. In other words, all memory cells 112 coupled to the same word line 119 may constitute a row of memory cells 120. The row of memory cells 120 may correspond to one or more memory pages. Different rows of memory cells 120 may be coupled to different word lines 119, respectively. Each word line 119 may be configured to have a select voltage or a deselect voltage applied thereto, and thus may become a selected word line or unselected word line.

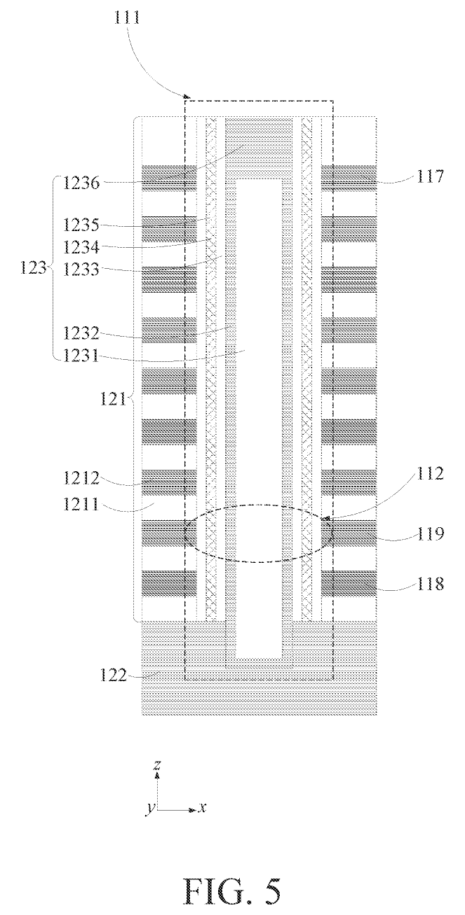

FIG. 5 shows a schematic diagram of a structure comprising a memory cell string provided by an example of the present disclosure. As shown in FIGS. 4 and 5, the memory cell string 111 may comprise a channel structure 123 extending vertically through a stacked structure 121 over a semiconductor layer 122. The material of the semiconductor layer 122 may comprise silicon (e.g., monocrystalline silicon), silicon germanium, gallium arsenide, germanium, or any other suitable semiconductor material. The semiconductor layer 122 may act as an ACS for one memory block 124.

It should be noted that the x-axis, y-axis, and z-axis shown in FIG. 5 are used to further illustrate the spatial relationship of the components of the memory. The semiconductor layer 122 may comprise two surfaces extending in a plane defined by the x-axis and the y-axis. The z-axis is perpendicular to the x-axis and the y-axis. When the semiconductor layer 122 is in the lowest plane of the memory in the z-direction, whether one component (e.g., layer or structure) of the memory is “on”, “above”, or “under”, “below” another component (e.g., layer or structure) in the z-direction is determined relative to the semiconductor layer 122. The same concept will be employed in the present disclosure to describe the spatial relationship of the components of the memory.

The stacked structure 121 may comprise dielectric layers 1211 and conductive layers 1212 that are alternately disposed. The number of pairs of dielectric layers 1121 and conductive layers 1212 may be used to determine the number of memory cells 112 in memory cell array 110. The material of the dielectric layer 1211 may comprise silicon oxide, silicon nitride, silicon oxynitride, or any other suitable insulating material. For example, the material of the dielectric layer 1211 may comprise silicon oxide. The material of the conductive layer 1212 may comprise one or more of titanium, titanium nitride, tantalum, tantalum nitride, polysilicon, amorphous silicon, tungsten, molybdenum, copper, aluminum, ruthenium, or any other suitable conductive material. For example, the material of the conductive layer 1212 may comprise tungsten. Each conductive layer 1212 may comprise a gate of the DSG transistor 114, a gate of the SSG transistor 113, or a gate of the memory cell 112, and may extend in an upper portion of the stacked structure 121 as a DSG line 117, extend in a lower portion of the stacked structure 121 as an SSG line 118, or extend in a middle portion of the stacked structure 121 as a word line 119.

It should be noted that although one SSG line 118 and one DSG line 117 are shown in FIGS. 4 and 5, in other examples the number of SSG lines 118 and the number of DSG lines 117 (and the number of SSG transistors 113 and DSG transistors 114 coupled to the SSG line 118 and DSG line 117, respectively) are variable, which is not limited in the present disclosure.

In some examples, as shown in FIG. 5, the channel structure 123 may be substantially cylindrical (e.g., cylindrical). The channel structure 123 may comprise an insulating pillar 1231, a channel layer 1232, a tunneling layer 1233, a charge trapping layer 1234, and a blocking layer 1235. The insulating pillars 1231 may extend along the z-direction into the semiconductor layer 122. The channel layer 1232, the tunneling layer 1233, the charge trapping layer 1234, and the blocking layer 1235 are sequentially disposed along a radial direction away from the insulating pillar 1231. In other words, the channel layer 1232 may surround the insulating pillar 1231, the tunneling layer 1233 may surround the channel layer 1232, the charge trapping layer 1234 may surround the tunneling layer 1233, and the blocking layer 1235 may surround the charge trapping layer 1234. For example, the channel layer 1232 may extend into the semiconductor layer 122, the tunneling layer 1233, the charge trapping layer 1234, and the blocking layer 1235 may extend only in the stacked structure 121 without extending into the semiconductor layer 122.

In some examples, the material of the insulating pillars 1231 may comprise one or more of silicon oxide, silicon nitride, silicon oxynitride, or any other suitable insulating material. The material of the channel layer 1232 may comprise one or more of polysilicon, amorphous silicon, germanium silicon, or any other suitable semiconductor material. The material of the tunneling layer 1233, the charge trapping layer 1234, and the blocking layer 1235 may sequentially comprise silicon oxide, silicon nitride, and silicon oxide.

In some examples, a portion of the channel structure 123 surrounded by the conductive layer 1212 and a portion of the conductive layer 1212 may constitute one memory cell 112, an SSG transistor 113, or a DSG transistor 114. The memory cell 112 may comprise a memory cell comprising a charge trap type transistor. As described above, other portions of conductive layer 1212 may act as a word line 119, an SSG line 118, or a DSG line 117. In one memory cell string 111, a plurality of memory cells 112 may share a channel layer 1232.

In some examples, as shown in FIGS. 4 and 5, the channel structure 123 may further comprise a trench plug 1236. The trench plug 1236 may be located above the insulating pillar 1231 and surrounded by, for example, the channel layer 1232. The material of the trench plug 1236 may comprise one or more of polysilicon, amorphous silicon, germanium silicon, or any other suitable semiconductor material. For example, the trench plug 1236 may act as the drain of the memory cell string 111. For example, the trench plug 1236 may be coupled with the bit line 116.

It should be noted that the structure of the memory cell string 111 shown in FIG. 5 is for illustrative purposes only and is variable in other examples.

In some examples, referring again to FIG. 3, the peripheral circuit 130 may comprise at least one of any suitable digital, analog, or mixed signal functional circuit, such as a row decoder (or referred to as a word line driver) 131, a column decoder (or referred to as a bit line driver) 133, a page buffer (or referred to as sense amplifier) 132, a voltage generator 134, a logic control circuit 135, an input/output (I/O) circuit 136, and a register 137, etc., for supporting the functions of the memory cell array 110. For example, the functional circuit described above may comprise one or more of any active or passive devices (e.g., transistors, diodes, resistors, or capacitors). It should be noted that in some examples, the peripheral circuit 130 may also comprise additional peripheral circuit not shown in FIG. 3.

As shown in FIGS. 3 and 4, the row decoder 131 may be configured to control a selected or unselected word line 119 in response to a control signal from the logic control circuit 135. The row decoder 131 may be further configured to drive the word line 119 using a word-line voltage (e.g., a word-line programming voltage, a pass voltage, etc.) generated from the voltage generator 134. In some examples, row decoder 131 may also select or deselect the SSG line 118 and the DSG line 117 using the SSG voltage and the DSG voltage generated from voltage generator 134.

As shown in FIGS. 3 and 4, the column decoder 133 may be configured to control a selected or unselected memory cell string 111 via the bit line 116 in response to a control signal from the logic control circuit 135. The column decoder 133 may be further configured to drive the bit line 116 using a bit-line voltage (e.g., a bit-line programming voltage, a bit-line inhibit voltage, and a bit-line intermediate voltage, etc.) generated from the voltage generator 134.

As shown in FIGS. 3 and 4, the page buffer 132 may be configured to read data from or program (write) data to the memory cell array 110 in response to a control signal from the logic control circuit 135. In one example, the page buffer 132 may store data to be programmed to one memory page of the memory cell array 110. In another example, the page buffer 132 may sense a low power signal of data stored in a memory cell of the memory cell array 110 during a read operation and amplify the small voltage swing to an identifiable logic level.

The voltage generator 134 may be configured to generate various voltages to be provided to the memory cell array 110, e.g., word-line voltages, bit-line voltages, SSG voltages, DSG voltages, and charging voltages, etc., in response to a control signal from the logic control circuit 135.

The logic control circuit 135 may be configured to generate various control signals and may comprise one or more logic control units. The logic control unit may comprise at least one of a software module or a firmware module running on a processor (for example, a microprogrammed control unit (MCU)) of a part of the logic control circuit 135, or may comprise a hardware module of a finite state machine (FSM), for example, an integrated circuit (for example, an application specific integrated circuit (ASIC), a field-programmable gate array (FPGA), and the like), or may comprise a combination of a software module, a firmware module, and a hardware module.

The input/output circuit 136 may transmit data to and from the page buffer 132 via a data bus and transmit, for example, at least one of addresses or commands to the logic control circuit 135. For example, the logic control circuit 135 may be configured to control the row decoder 131, the column decoder 133, and the page buffer 132 in response to commands transmitted from the input/output circuit 136.

The register 137 may be coupled to the logic control circuit 135 and may comprise a status register, a command register, an address register, etc., for storing operation status information, command operation codes, and command addresses for controlling each peripheral circuit.

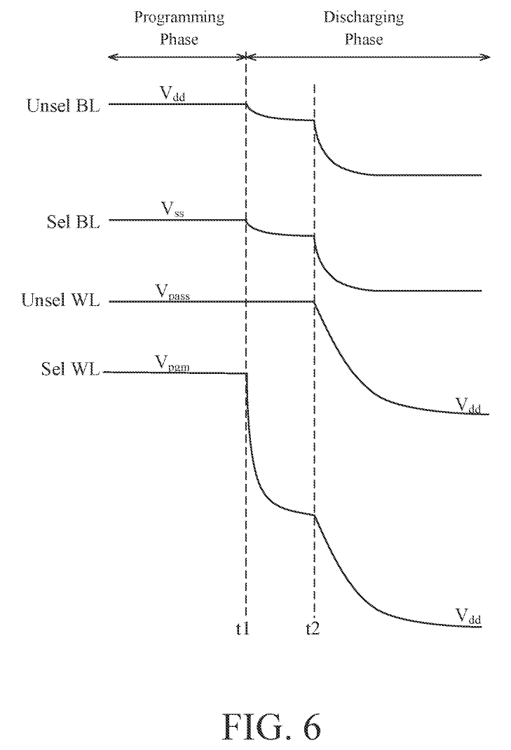

FIG. 6 is a schematic waveform diagram of a selected word line, a selected bit line, an unselected word line, and an unselected bit line in a programming phase and a discharging phase provided by an example of the present disclosure. As shown in FIGS. 3-6, during a program operation (e.g., in a programming phase), a word-line programming voltage V_{pgm} (e.g., a positive voltage between 10V and 20V) may be provided to the selected word line Sel WL by the row decoder 131 in response to a control signal from the logic control circuit 135, and a bit-line programming voltage (e.g., a ground voltage Vₛₛ) may be provided to the selected bit line Sel BL by the column decoder 133 in response to a control signal from the logic control circuit 135. Meanwhile, the pass voltage Vₚₐₛₛ (e.g., a positive voltage less than 10V) may be provided to the unselected word line Unsel WL by the row decoder 131 in response to a control signal from the logic control circuit 135. The selected bit line Sel BL may be a bit line coupled with the selected memory cell string.

As such, the ground voltage Vₛₛ (e.g., 0V) on the selected bit line Sel BL is conducted to the channel (e.g., the channel layer 1232 shown in FIG. 5), the DSG transistor 114 is controlled by the DSG line 117 to be in a turn-on state, and the SSG transistor 113 is controlled by the SSG line 118 to be in a turn-off state. The selected memory cell is controlled by the selected word line Sel WL and the selected bit line Sel BL, and the voltage difference between the word-line programming voltage V_{pgm} and the bit-line programming voltage (e.g., ground voltage Vₛₛ) causes charges to be injected into the charge trapping layer 1234 or floating gate (not shown) of the selected memory cell, thereby increasing the threshold voltage of the selected memory cell, which in turn programs the selected memory cell to different data states.

Further, in the programming phase, a bit-line inhibit voltage (e.g., power supply voltage V_{dd}) may be provided to an unselected bit line Unsel BL by the column decoder 133 in response to a control signal from the logic control circuit 135. The unselected bit line Unsel BL may be a bit line coupled with the unselected memory cell string. Since the voltage difference between the word-line programming voltage V_{pgm} and the bit-line inhibit voltage (e.g., the power supply voltage V_{dd}) is insufficient to cause charges to be injected into the charge trapping layer 1234 or the floating gate (not shown) of the selected memory cell, the data states of other unselected memory cells coupled with the selected word line Sel WL will not be changed.

After the programming phase, the selected word line Sel WL and the unselected word line Unsel WL need to be discharged (e.g., both discharged to the power supply voltage V_{dd}). As shown in FIG. 5, for one memory cell 112, the word line 119 and the channel layer 1232 are separated by the tunneling layer 1333, the charge trapping layer 1324, and the blocking layer 1235, which may equivalently constitute a capacitor. In addition, an upper end of the channel layer 1232 is coupled with the bit line 116. During the discharging phase, the bit line 116 (e.g., the selected bit line Sel BL and the unselected bit line Unsel BL) are both in a floating state, and due to the coupling effect of the capacitor, the discharging process of the word line (e.g., the selected word line Sel WL) pulls down the voltage of the bit line 116 (e.g., the selected bit line Sel BL and the unselected bit line Unsel BL). Especially for the selected bit line Sel BL, an excessively low voltage may cause latch-up effect of the peripheral circuit coupled thereto.

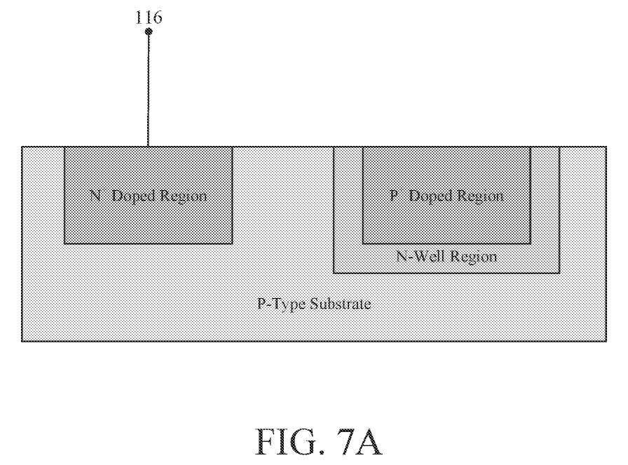

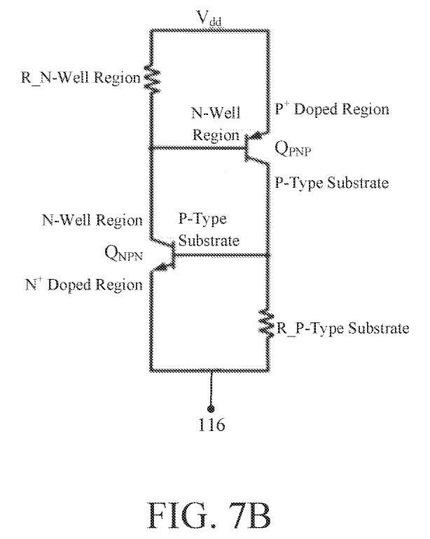

FIG. 7A shows a schematic diagram of a structure of a peripheral circuit coupled with a bit line provided by an example of the present disclosure. FIG. 7B is an equivalent circuit diagram of the bit line and the peripheral circuit coupled with the bit line shown in FIG. 7A. The latch-up effect will be described below with reference to FIGS. 7A and 7B.

As shown in FIG. 7A, the peripheral circuit coupled with the bit line 116 may be fabricated by CMOS processes, and the peripheral circuit may comprise an NMOS active region (e.g., a N⁺ doped region), a P-type substrate, a N-well region, a PMOS active region (e.g., a P⁺ doped region), wherein these regions may constitute an N-P-N-P structure. The N-P-N-P structure may be equivalently represented by the circuit diagram shown in FIG. 7B, wherein the R_N-well region may correspond to the parasitic resistance of the N-well region shown in FIG. 7A, the R_P-type substrate may correspond to the parasitic resistance of the P-type substrate shown in FIG. 7A. For example, when the voltage of the bit line 116 decreases to a level that generates current flow through the parasitic resistor R_N-well region, the base voltage of the transistor Q_{PNP} decreases. When this voltage reduction causes forward biasing of the emitter of the transistor Q_{PNP}, the transistor Q_{PNP} is turned on, allowing the current to flow through the parasitic resistor R_P-type substrate. This current flow subsequently forward-biases the emitter of the transistor Q_{NPN}, and the current through the parasitic resistor R_N-well region is further increased, thereby establishing a positive feedback loop. In this way, the current circulating through the loop formed by the two transistors Q_{PNP} and Q_{NPN} undergoes continuous amplification, ultimately leading to excessive current through both transistors that may thermally destroy the memory device.

The present disclosure provides a memory that improves the latch-up effect and reduces the risk of burning out the memory by optimizing the configuration of the peripheral circuit. The configuration scheme of the peripheral circuit of the memory will be described in detail below.

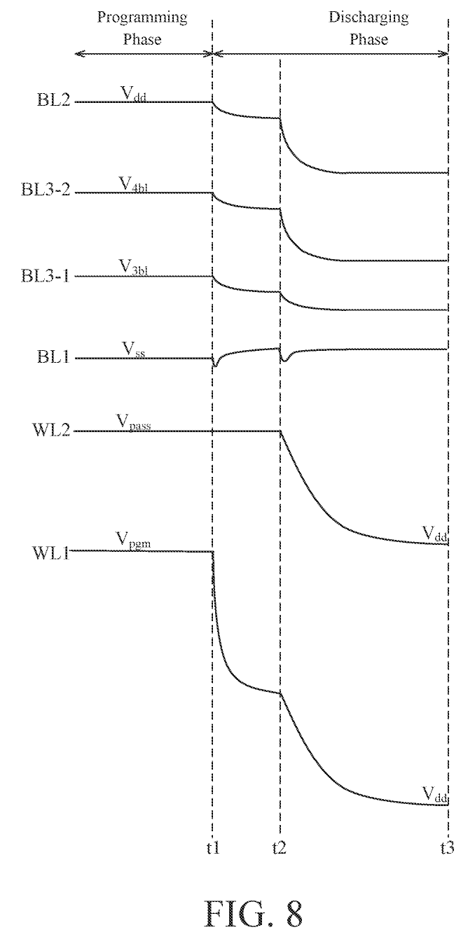

FIG. 8 shows a schematic waveform diagram in a programming phase and a discharging phase including a first word line and a first bit line provided by an example of the present disclosure.

As shown in FIG. 8, in the programming phase, a word-line programming voltage V_{pgm} may be provided to a first word line WL1. For example, with reference to FIG. 3, the word-line programming voltage V_{pgm} (e.g., a positive voltage between 10V and 20V) may be provided to the first word line WL1 by the row decoder 131 in response to a control signal from the logic control circuit 135. The first word line WL1 may be a selected word line. The first word line WL1 may be coupled with a plurality of memory cells. The plurality of memory cells may comprise a selected memory cell (e.g., a first memory cell). The first memory cell may be coupled with the first bit line BL1. The first bit line BL1 may be a selected bit line.

In some examples, as shown in FIG. 8, during the programming phase, a pass voltage Vₚₐₛₛ may also be provided to a second word line WL2. For example, with reference to FIG. 3, the pass voltage Vₚₐₛₛ (e.g., less than 10V) may be provided to the second word line WL2 by the row decoder 131 in response to a control signal from the logic control circuit 135. The second word line WL2 may be an unselected word line. Therefore, the second word line WL2 may comprise a plurality of second word lines. In general, the pass voltage Vₚₐₛₛ may be less than the word-line programming voltage V_{pgm}. A plurality of unselected memory cells other than the first memory cell in the same memory cell string 111 are respectively coupled with the plurality of second word lines WL2. These unselected memory cells are controlled by the second word line WL2 and are in the turn-on state under the action of the pass voltage Vₚₐₛₛ.

As shown in FIG. 8, in the programming phase, a bit-line programming voltage may also be provided to the first bit line BL1. For example, with reference to FIG. 3, a bit-line programming voltage may be provided to the first bit line BL1 by the column decoder 133 in response to a control signal from the logic control circuit 135. In one example, the bit-line programming voltage may comprise a ground voltage Vₛₛ (e.g., 0V). Hereinafter, taking the bit-line programming voltage being the ground voltage Vₛₛ as an example for description. However, it should be noted that the bit-line programming voltage may further comprise other voltages having a smaller positive voltage value or a negative voltage value, as long as the voltage difference between the word-line programming voltage V_{pgm} and the bit-line programming voltage is greater than the voltage threshold that enables the charges to be injected into the charge trapping layer 1234 (referring to FIG. 5) or the floating gate of the selected memory cell, and the specific value of the bit-line programming voltage is not limited in the present disclosure.

In some examples, as shown in FIG. 8, during the programming phase, a bit-line inhibit voltage may also be provided to a second bit line BL2. For example, with reference to FIG. 3, the bit-line inhibit voltage may be provided to the second bit line BL2 by the column decoder 133 in response to a control signal from the logic control circuit 135. The second bit line BL2 may be an unselected bit line. Other than the first memory cell, a second memory cell among the plurality of memory cells coupled with the first word line WL1 may be coupled with the second bit line BL2. The bit-line programming voltage Vₛₛ may be less than the bit-line inhibit voltage. As an example, the bit-line inhibit voltage may comprise the power supply voltage V_{dd}. Hereinafter, taking the bit-line inhibit voltage being the power supply voltage V_{dd} as an example for description.

In some examples, as shown in FIG. 8, during the programming phase, bit-line intermediate voltages (e.g., V_{3bl} and V_{4bl}) may be provided to third bit lines (e.g., BL3-1 and BL3-2). For example, with reference to FIG. 3, the bit-line intermediate voltages (e.g., V_{3bl} and V_{4bl}) may be provided to the third bit lines (e.g., BL3-1 and BL3-2) by the column decoder 133 in response to a control signal from the logic control circuit 135. Other than the first memory cell and the second memory cell, a plurality of third memory cells among the plurality of memory cells coupled with the first word line WL1 may be coupled with a plurality of the third bit lines (e.g., BL3-1 and BL3-2), respectively. The bit-line intermediate voltages (e.g., V_{3bl} and V_{4bl}) may be greater than the bit-line programming voltage Vₛₛ and less than the bit-line inhibit voltage V_{dd}, and the plurality of bit-line intermediate voltages (e.g., V_{3bl} and V_{4bl}) are different from each other.

The following describes the bit-line intermediate voltages (e.g., V_{3bl} and V_{4bl}).

In the process of programming a memory cell to a target data state, an increment step programming pulse (ISPP) method is employed to program. In an example, the ISPP scheme consists of a series of program-verify operations, and after each programming operation, whether the memory cell has reached the target data state or not is determined by the verify operation. If the memory cell does not reach the target data state, the memory cell is further programmed until the requirement of the verify voltage is satisfied. The word-line programming voltage V_{pgm} used in the plurality of programming operations performed sequentially may be incrementally increased by adding a step pulse increment. Once faster-programming memory cells reach the target data state, their programming is inhibited. Only slower-programming memory cells continue to receive higher programming voltages until they achieve the target data state.

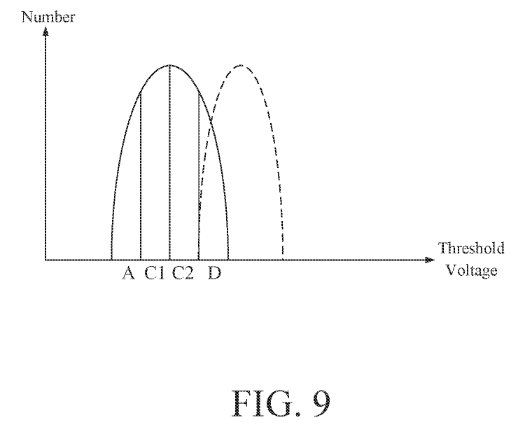

FIG. 9 shows a schematic diagram of a distribution of threshold voltages of a first memory cell, a second memory cell, and a third memory cell provided by an example of the present disclosure. As shown in FIG. 9, the solid line represents the threshold voltage distribution of the plurality of memory cells coupled with the first word line WL1 determined after the current program-verify operation. The dashed line represents the threshold voltage distribution of the plurality of memory cells described above after a subsequent program-verify operation. For example, the dashed line represents the threshold voltage distribution of the target data state. The threshold voltage of the first memory cell may be located in the voltage interval A, the threshold voltage of the second memory cell may be located in the voltage interval B, and the threshold voltage of the third memory cell may be located in the voltage intervals C1 and C2.

Since the distribution difference between the threshold voltage of the first memory cell and the threshold voltage of the target data state is large, the bit-line programming voltage Vₛₛ can be provided to the first bit line BL1 coupled with the first memory cell in the programming phase of the subsequent program-verify operation, so that the first memory cell is further programmed. Since the threshold voltage of the second memory cell has reached the threshold voltage distribution of the target data state, the bit-line inhibit voltage V_{dd} can be provided to the second bit line BL2 coupled with the second memory cell, so that the second memory cell is inhibited from being programmed to maintain the current threshold voltage. Since the threshold voltage of the third memory cell has not reached the threshold voltage distribution of the target data state, but the distribution difference between the threshold voltage of the third memory cell and the threshold voltage of the target data state is small, the bit-line intermediate voltages V_{3bl} and V_{4bl} between the bit-line inhibit voltage V_{dd} and the bit-line programming voltage Vₛₛ can be provided to the third memory cell.

The distribution difference between the threshold voltage of the third memory cell located in the voltage interval C1 and the threshold voltage of the target data state is greater than the distribution difference between the threshold voltage of the third memory cell located in the voltage interval C2 and the threshold voltage of the target data state, so that the bit-line intermediate voltage V_{3bl} may be provided to the third bit line BL3-1 coupled with the third memory cell located in the voltage interval C1, and the bit-line intermediate voltage V_{4bl} may be provided to the third bit line BL3-2 coupled with the third memory cell located in the voltage interval C2, wherein V_{4bl} is greater than V_{3bl}, so that the programming degree (e.g., the number of injected charges) of the third memory cell located in the voltage interval C1 is greater than the programming degree of the third memory cell located in the voltage interval C2. In this way, the difference in electrical characteristics caused by unevenness between the memory cells can be improved, thereby obtaining a narrower target threshold voltage distribution and increasing the reading window.

It should be noted that, in the above description, determining the third memory cell to be within two different voltage intervals C1 and C2 and providing two different bit-line intermediate voltages V_{3bl} and V_{4bl} to different third bit lines BL3-1 and BL3-2 coupled with the third memory cells located in the two voltage intervals C1 and C2 respectively are only examples, and in other examples, the third memory cell may be determined to be located in more ( for example, more than 2) different voltage intervals, and more different bit-line intermediate voltages can be provided to different third bit lines coupled with the third memory cells located in different voltage intervals respectively, to obtain a narrower target threshold voltage distribution, and further increase the reading window.

Referring again to FIG. 8, after the programming phase, e.g., from a first point of time t1, the first word line WL1 may be discharged from the word-line programming voltage V_{pgm}. As an example, from the first point of time t1 to the third point of time t3 may be referred to as a discharging phase. For example, with reference to FIG. 3, the first word line WL1 may be coupled with a discharge circuit (not shown) in the peripheral circuit 130, and the discharge circuit is controlled to be connected with the first word line WL1 in response to a control signal from the logic control circuit 135, so that the voltage of the first word line WL1 is decreased from the word-line programming voltage V_{pgm} to the power supply voltage V_{dd}.

In some examples, during the discharging phase, the first word line WL1 may be discharged from the word-line programming voltage V_{pgm} in steps. As an example, as shown in FIG. 8, during the discharging phase, from the first point of time t1 to a second point of time t2, a first step of discharging is performed on the first word line WL1. Subsequently, from the second point of time t2 to the third point of time t3, a second step of discharging is performed on the first word line WL1. For example, the discharging rates in the two steps are different. For example, a voltage value of a voltage drop of the first word line WL1 from the first point of time t1 to the second point of time t2 is different from a voltage value of a voltage drop of the first word line WL1 from the second point of time t2 to the third point of time t3. Since the word-line programming voltage V_{pgm} has a larger voltage value, step-wise discharging is adopted to help to provides a buffering effect for the discharging circuit.

It should be noted that although the discharging phase of the first word line WL1 is illustrated by using a two-step discharging as an example, in other examples, during the entire discharging phase, the first word line WL1 can be discharged in a single step or more steps, which is not limited in the present disclosure.

In some examples, as shown in FIG. 8, after the programming phase (e.g., in the discharging phase), the second word line WL2 may also be discharged from the pass voltage Vₚₐₛₛ. The pass voltage Vₚₐₛₛ is less than the word-line programming voltage V_{pgm}. For example, with reference to FIG. 3, the second word line WL2 may be coupled with a discharge circuit (not shown) in the peripheral circuit 130, and the discharge circuit is controlled to be connected with the second word line WL2 in response to a control signal from the logic control circuit 135, so that the voltage of the second word line WL2 is decreased from the pass voltage Vₚₐₛₛ to the power supply voltage V_{dd}. In some examples, in the time period from the second point of time t2 to the third point of time t3, the second word line WL2 may be discharged. Since the pass voltage Vₚₐₛₛ is less than the word-line programming voltage V_{pgm}, the starting point of time (e.g., the second point of time t2) of discharging the second word line WLb is later than the starting point of time (e.g., the first point of time t1) of discharging the first word line WL1, so that the first word line WL1 and the second word line WL2 can be discharged to the same power supply voltage V_{dd} at substantially the same discharging rate in the same time of period.

With continued reference to FIG. 8, in the process of discharging the first word line WL1 from the word-line programming voltage V_{pgm}, e.g., from the first point of time t1, a charging voltage may be provided to the first bit line BL1. For example, with reference to FIG. 3, the first bit line BL1 may be coupled with the page buffer 132, and the charging path is controlled to be connected with the first bit line BL1 in response to the control signal from the logic control circuit 135 to provide the charging voltage to the first bit line BL1.

Since the voltage of the first word line WL1 decreases from the first point of time t1, the voltage of the first bit line BL1 decreases within a shorter time period after the first point of time t1 under the coupling effect of the first word line WL1. Then the voltage of the first bit line BL1 rises under the action of the charging voltage. In other words, from the first point of time t1, the voltage of the first bit line BL1 first decreases and then increases. Since the voltage drop of the first bit line BL1 occurs within a shorter time period after the first point of time t1, the overall trend of the voltage of the first bit line BL1 is upward. In this way, under the action of the charging voltage, the first bit line BL1 would not decrease to a critical voltage value that triggers the latch-up effect, thereby effectively mitigating the latch-up effect, reducing the risk of burning out the memory, and improving the reliability of the memory.

In some examples, in a case where the first word line WL1 is discharged in steps, since a fall rate of the voltage of the first word line WL1 changes from the starting point of time (for example, the second point of time t2) of the subsequent step of discharging, the voltage of the first bit line BL1 may also first decrease and then increase from the second point of time t2. Similarly, since the voltage drop of the first bit line BL1 occurs within a shorter time period after the second point of time t2, the overall trend of the voltage of the first bit line BL1 is upward from the second point of time t2 to the third point of time t3. At respective steps of discharging of the first word line WL1, rise rates of a voltage of the first bit line BL1 differ from each other.

In other examples, the charging voltage is provided to the first bit line BL1 during a discharging phase, such as from a certain point of time later than the first point of time t1. In other words, the starting point of time at which the charging voltage is provided to the first bit line BL1 may be later than the starting point of time at which the first word line WL1 is discharged. In this way, from the first point of time t1 to the starting point of time at which the charging voltage is provided to the first bit line BL1, the voltage of the first bit line BL1 continues to decrease. It can be ensured that the voltage of the first bit line BL1 would not drop to the critical voltage value that triggers the latch-up effect by reasonably setting the starting point of time at which the charging voltage is provided to the first bit line BL1.

In some examples, after the programming phase (e.g., in the discharging phase), the second bit line BL2 may be controlled to be in a floating state. For example, with reference to FIG. 3, the second bit line BL2 may be coupled with the page buffer 132, and the charging path is controlled to be disconnected from the second bit line BL2 in response to the control signal from the logic control circuit 135, so that the second bit line BL2 is in the floating state. Under the coupling effect with the first word line WL1, the voltage of the second bit line BL2 continues to decrease. Since the voltage of the second bit line BL2 (e.g., the bit-line inhibit voltage V_{dd}) is high at the end of the programming phase (e.g., the first point of time t1), the voltage of the second bit line BL2 would not decrease to a critical voltage value that triggers the latch-up effect, thereby effectively mitigating the latch-up effect, reducing the risk of burning out the memory, and improving the reliability of the memory.

In some examples, in a case where the first word line WL1 is discharged in steps, similarly, since the fall rate of the voltage of the first word line WL1 changes from the starting point of time (for example, the second point of time t2) of the subsequent step of discharging, the fall rate of the voltage of the second bit line BL2 after the second point of time t2 is different from the fall rate of the voltage of the second bit line BL2 from the first point of time t1 to the second point of time t2.

In some examples, as shown in FIG. 8, after the programming phase (e.g., in the discharging phase), a charging voltage is provided to a first set of third bit lines (e.g., third bit line BL3-1) among the plurality of third bit lines and a second set of third bit lines (e.g., third bit line BL3-2) among the plurality of third bit lines are controlled to be in a floating state. A bit-line intermediate voltage V_{3bl} provided to the first set of third bit lines (for example, the third bit line BL3-1) is less than a preset threshold, and a bit-line intermediate voltage V_{4bl} provided to the second set of third bit lines (for example, the third bit line BL3-2) is greater than the preset threshold.

For example, with reference to FIG. 3, the first set of third bit lines (e.g., third bit line BL3-1) may be coupled with the page buffer 132, and a charging path is controlled to be connected with the first set of third bit lines (e.g., third bit line BL3-1) in response to a control signal from the logic control circuit 135 to provide a charging voltage to the first set of third bit lines (e.g., third bit line BL3-1). As another example, the second set of third bit lines (e.g., third bit line BL3-2) may be coupled with the page buffer 132, and a charging path is controlled to be connected with the second set of third bit lines (e.g., third bit line BL3-2) in response to a control signal from the logic control circuit 135 to cause the second set of third bit lines (e.g., third bit line BL3-2) to be in the floating state.

In the above examples, under the action of the charging voltage, the first set of third bit lines (e.g., the third bit line BL3-1) will not further decrease (e.g., can maintained at the charging voltage) to a critical voltage value that triggers the latch-up effect, thereby effectively mitigating the latch-up effect, reducing the risk of burning out the memory, and improving the reliability of the memory. In addition, under the coupling effect with the first word line WL1, the voltage of the second set of third bit lines (e.g., the third bit line BL3-2) will continue to decrease, since the voltage of the second set of third bit lines (e.g., the third bit line BL3-2) is higher (e.g., the bit-line intermediate voltage V_{4bl} is greater than the preset threshold) at the end of the programming phase (e.g., at the first point of time t1), and the voltage of the second set of third bit lines (e.g., the third bit line BL3-2) will not decrease to a critical voltage value that triggers the latch-up effect, thereby effectively mitigating the latch-up effect, reducing the risk of burning out the memory, and improving the reliability of the memory.

In some examples, during the discharging phase, a charging voltage may be provided to a first set of third bit lines (e.g., third bit line BL3-1) among the plurality of third bit lines from a first point of time t1. In some other examples, during the discharging phase, a charging voltage may be provided to the first set of third bit lines (e.g., third bit line BL3-1) from a certain point of time later than the first point of time t1, which is not limited in the present disclosure.

It should be noted that, in the above description, the first set of third bit lines and the second set of third bit lines are merely examples, and when the number of third bit lines with different bit-line intermediate voltages is greater than 2, the respective numbers of the third bit lines in the first set and the second set may also depend on the voltage values of the bit-line intermediate voltages, and the specific respective numbers of the third bit lines in the first set and the second set are not limited in the present disclosure.

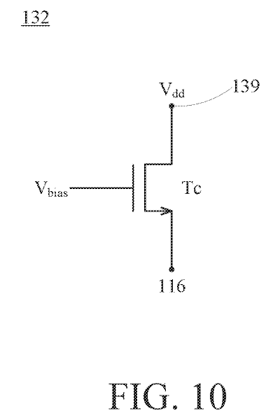

FIG. 10 shows a partial circuit diagram of a page buffer provided by an example of the present disclosure. It should be noted that FIG. 10 is only a portion of the page buffer 132 shown in FIG. 3, and the page buffer 132 may also comprise other circuit portions. The number of page buffers 132 may correspond to the number of bit lines 116. For example, each bit line 116 (e.g., first bit line BL1, second bit line BL2, third bit lines BL3-1 and BL3-2) may be coupled with one page buffer 132. The page buffer 132 may comprise a clamp transistor Tc. A first terminal of the clamp transistor Tc is coupled with each bit line 116 (e.g., the first bit line BL1, the second bit line BL2, the third bit lines BL3-1 and BL3-2), and a second terminal of the clamp transistor Tc is coupled with the power supply terminal 139. In other words, each bit line 116 (e.g., the first bit line BL1, the second bit line BL2, the third bit lines BL3-1 and BL3-2) is coupled with the power supply terminal 139 through one clamp transistor Tc, respectively. The power supply terminal 139 is configured to provide a power supply voltage V_{dd}.

In some examples, the clamp transistor Tc may comprise an NMOS transistor. For example, the first terminal of the clamp transistor Tc may be the source terminal, and the second terminal of the clamp transistor Tc may be the drain terminal. In other examples, the clamp transistor Tc may also comprise a PMOS transistor.

In some examples, in the process of providing the charging voltage to the first bit line BL1, a bias voltage V_{bias} may be provided to control terminals (e.g., gate) of a plurality of clamp transistors Tc, so that clamp transistors Tc among the plurality of clamp transistors Tc coupled with the first bit line BL1 and the first set of third bit lines (e.g., the third bit line BL3-1) are in a turn-on state, and clamp transistors Tc among the plurality of clamp transistors Tc coupled with the second bit line BL2 and the second set of third bit lines (e.g., the third bit line BL3-2) are in a turn-off state.

Taking the clamp transistor Tc being an NMOS transistor as an example, for example, the voltage value of the bias voltage V_{bias} may be the sum of the preset threshold and the threshold voltage of the clamp transistor Tc. At the starting point of time (e.g., the first point of time t1) at which the charging voltage is provided to the first bit line BL1, the voltage of the first bit line BL1 has a smaller value (e.g., the ground voltage Vₛₛ). In response to receiving the bias voltage V_{bias} at the control terminal (e.g., gate) of the clamp transistor Tc coupled with the first bit line BL1, the clamp transistor Tc coupled with the first bit line BL1 may be in the turn-on state, the first bit line BL1 is connected with the power supply terminal 139, and the power supply terminal 139 provides the charging voltage to the first bit line BL1.

In the process of providing the charging voltage to the first bit line BL1, in response to receiving the bias voltage V_{bias} at the control terminal (e.g., the gate) of the clamp transistor Tc coupled with the first set of third bit lines (e.g., the third bit line BL3-1), since the voltage of the first set of third bit lines (e.g., third bit line BL3-1) is less than the preset threshold, the clamp transistor Tc coupled with the first set of third bit lines (e.g., the third bit line BL3-1) may be in the turn-on state, the first set of third bit lines (e.g., the third bit line BL3-1) are connected with the power supply terminal 139, and the power supply terminal 139 provides the charging voltage to the first set of third bit lines (e.g., the third bit line BL3-1).

In the process of providing the charging voltage to the first bit line BL1, in response to receiving the bias voltage V_{bias} at the control terminal (e.g., the gate) of the clamp transistor Tc coupled with the second bit line BL2, since the voltage of the second bit line BL2 has a larger value (e.g., the power supply voltage V_{dd}), the voltage of the second bit line BL2 drops but will not turn on the clamp transistor Tc coupled thereto, thus the clamp transistor Tc is in the turn-off state. Thus, the second bit line BL2 is disconnected from the power supply terminal 139 and is in a floating state.

In the process of providing the charging voltage to the first bit line BL1, in response to receiving the bias voltage V_{bias} at the control terminal (e.g., the gate) of the clamp transistor Tc coupled with the second set of third bit lines (e.g., third bit line BL3-2), since the voltage of the second set of third bit lines (e.g., the third bit line BL3-2) is greater than the preset threshold, the voltage of the second set of third bit lines (e.g., the third bit line BL3-2) drops but may not turn on the clamp transistor Tc coupled thereto, thus the clamp transistor Tc is in the turn-off state. As such, the second set of third bit lines (e.g., third bit line BL3-2) are disconnected from the power supply terminal 139 and are in a floating state.

In some examples, as shown in FIG. 10, the page buffer 132 may further comprise one or more switching units (not shown). For example, one or more switching units are coupled between the clamp transistor Tc and the power supply terminal 139, and/or one or more switching units are coupled between the clamp transistor Tc and the bit line 116. For example, during the discharging phase, one or more switching units may be configured to be in a turn-on state. For example, the switching unit may comprise a transistor.

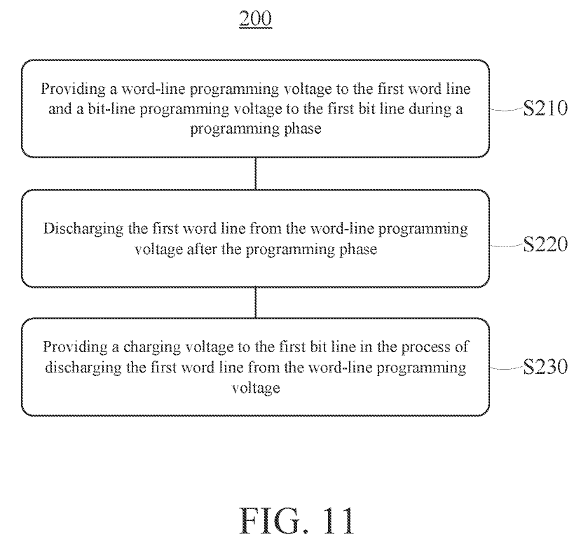

FIG. 11 illustrates an operating method for a memory provided by an example of the present disclosure. As shown in FIG. 11, the operating method 200 for the memory may comprise the following operations:

At S210: providing a word-line programming voltage to the first word line and a bit-line programming voltage to the first bit line during a programming phase.

At S220: discharging the first word line from the word-line programming voltage after the programming phase.

At S230: providing a charging voltage to the first bit line in the process of discharging the first word line from the word-line programming voltage.

Details of the operations of the operating method 200 for the memory will be described in detail below with reference to FIG. 3 to FIG. 10.

At operation S210, as shown in FIG. 8, in the programming phase, a word-line programming voltage V_{pgm} may be provided to a first word line WL1. For example, with reference to FIG. 3, the word-line programming voltage V_{pgm} (e.g., a positive voltage between 10V and 20V) may be provided to the first word line WL1 by the row decoder 131 in response to a control signal from the logic control circuit 135. The first word line WL1 may be a selected word line. The first word line WL1 may be coupled with a plurality of memory cells. The plurality of memory cells may comprise a selected memory cell (e.g., a first memory cell). The first memory cell may be coupled with the first bit line BL1. The first bit line BL1 may be a selected bit line.

In some examples, as shown in FIG. 8, during the programming phase, a pass voltage Vₚₐₛₛ may also be provided to a second word line WL2. For example, with reference to FIG. 3, the pass voltage Vₚₐₛₛ (e.g., less than 10V) may be provided to the second word line WL2 by the row decoder 131 in response to a control signal from the logic control circuit 135. The second word line WL2 may be an unselected word line. Therefore, the second word line WL2 may comprise a plurality of second word lines. In general, the pass voltage Vₚₐₛₛ may be less than the word-line programming voltage V_{pgm}. A plurality of unselected memory cells other than the first memory cell in the same memory cell string 111 are respectively coupled with the plurality of second word lines WL2. These unselected memory cells are controlled by the second word lines WL2 and are in the turn-on state under the action of the pass voltage Vₚₐₛₛ.

At operation S210, as shown in FIG. 8, in the programming phase, a bit-line programming voltage may also be provided to the first bit line BL1. For example, with reference to FIG. 3, the bit-line programming voltage may be provided to the first bit line BL1 by the column decoder 133 in response to a control signal from the logic control circuit 135. In one example, the bit-line programming voltage may comprise a ground voltage Vₛₛ (e.g., 0V). Hereinafter, taking the bit-line programming voltage being the ground voltage Vₛₛ as an example for description. However, it should be noted that the bit-line programming voltage may further comprise other voltages having a smaller positive voltage value or a negative voltage value, as long as the voltage difference between the word-line programming voltage V_{pgm} and the bit-line programming voltage is greater than the voltage threshold that enables the charges to be injected into the charge trapping layer 1234 (referring to FIG. 5) or the floating gate of the selected memory cell, and the specific value of the bit-line programming voltage is not limited in the present disclosure.

In some examples, as shown in FIG. 8, during the programming phase, a bit-line inhibit voltage may also be provided to a second bit line BL2. For example, with reference to FIG. 3, the bit-line inhibit voltage may be provided to the second bit line BL2 by the column decoder 133 in response to a control signal from the logic control circuit 135. The second bit line BL2 may be an unselected bit line. Other than the first memory cell, a second memory cell among the plurality of memory cells coupled with the first word line WL1 may be coupled with the second bit line BL2. The bit-line programming voltage Vₛₛ may be less than the bit-line inhibit voltage. As an example, the bit-line inhibit voltage may comprise the power supply voltage V_{dd}. Hereinafter, taking the bit-line inhibit voltage being the power supply voltage V_{dd} as an example for description.

In some examples, as shown in FIG. 8, during the programming phase, bit-line intermediate voltages (e.g., V_{3bl} and V_{4bl}) may be provided to third bit lines (e.g., BL3-1 and BL3-2). For example, with reference to FIG. 3, the bit-line intermediate voltages (e.g., V_{3bl} and V_{4bl}) may be provided to the third bit lines (e.g., BL3-1 and BL3-2) by the column decoder 133 in response to a control signal from the logic control circuit 135. Other than the first memory cell and the second memory cell, a plurality of third memory cells among the plurality of memory cells coupled with the first word line WL1 may be coupled with a plurality of the third bit lines (e.g., BL3-1 and BL3-2), respectively. The bit-line intermediate voltages (e.g., V_{3bl} and V_{4bl}) may be greater than the bit-line programming voltage Vₛₛ and less than the bit-line inhibit voltage V_{dd}, and the plurality of bit-line intermediate voltages (e.g., V_{3bl} and V_{4bl}) are different from each other.

It should be noted that the bit-line intermediate voltages (e.g., V_{3bl} and V_{4bl}) have been described above, which will not be repeated here.

At operation S220, after the programming phase, e.g., from a first point of time t1, the first word line WL1 may be discharged from the word-line programming voltage V_{pgm}. As an example, from the first point of time t1 to the third point of time t3 may be referred to as a discharging phase. For example, with reference to FIG. 3, the first word line WL1 may be coupled with a discharge circuit (not shown) in the peripheral circuit 130, and the discharge circuit is controlled to be connected with the first word line WL1 in response to a control signal from the logic control circuit 135, so that the voltage of the first word line WL1 is decreased from the word-line programming voltage V_{pgm} to the power supply voltage V_{dd}.

In some examples, during the discharging phase, the first word line WL1 may be discharged from the word-line programming voltage V_{pgm} in steps. As an example, as shown in FIG. 8, during the discharging phase, from the first point of time t1 to a second point of time t2, a first step of discharging is performed on the first word line WL1. Subsequently, from the second point of time t2 to the third point of time t3, a second step of discharging is performed on the first word line WL1. For example, the discharging rates in the two steps are different. For example, a voltage value of a voltage drop of the first word line WL1 from the first point of time t1 to the second point of time t2 is different from a voltage value of a voltage drop of the first word line WL1 from the second point of time t2 to the third point of time t3. Since the word-line programming voltage V_{pgm} has a larger voltage value, step-wise discharging is adopted to help to provides a buffering effect for the discharging circuit.

It should be noted that although the discharging phase of the first word line WL1 is illustrated by using a two-step discharging as an example, in other examples, during the entire discharging phase, the first word line WL1 can be discharged in a single step or more steps, which is not limited in the present disclosure.

In some examples, as shown in FIG. 8, after the programming phase (e.g., in the discharging phase), the second word line WL2 may also be discharged from the pass voltage Vₚₐₛₛ. The pass voltage Vₚₐₛₛ is less than the word-line programming voltage V_{pgm}. For example, with reference to FIG. 3, the second word line WL2 may be coupled with a discharge circuit (not shown) in the peripheral circuit 130, and the discharge circuit is controlled to be connected with the second word line WL2 in response to a control signal from the logic control circuit 135, so that the voltage of the second word line WL2 is decreased from the pass voltage Vₚₐₛₛ to the power supply voltage V_{dd}. In some examples, in the time period from the second point of time t2 to the third point of time t3, the second word line WL2 may be discharged. Since the pass voltage Vₚₐₛₛ is less than the word-line programming voltage V_{pgm}, the starting point of time (e.g., the second point of time t2) of discharging the second word line WL2 is later than the starting point of time (e.g., the first point of time t1) of discharging the first word line WL1, so that the first word line WL1 and the second word line WL2 can be discharged to the same power supply voltage V_{dd} at substantially the same discharging rate in the same time of period.

At operation S230, with continued reference to FIG. 8, in the process of discharging the first word line WL1 from the word-line programming voltage V_{pgm}, e.g., from the first point of time t1, a charging voltage may be provided to the first bit line BL1. For example, with reference to FIG. 3, the first bit line BL1 may be coupled with the page buffer 132, and the charging path is controlled to be connected with the first bit line BL1 in response to the control signal from the logic control circuit 135 to provide the charging voltage to the first bit line BL1.

Since the voltage of the first word line WL1 decreases from the first point of time t1, the voltage of the first bit line BL1 decreases within a shorter time period after the first point of time t1 under the coupling effect of the first word line WL1. Then the voltage of the first bit line BL1 rises under the action of the charging voltage. In other words, from the first point of time t1, the voltage of the first bit line BL1 first decreases and then increases. Since the voltage drop of the first bit line BL1 occurs within a shorter time period after the first point of time t1, the overall trend of the voltage of the first bit line BL1 is upward. In this way, under the action of the charging voltage, the first bit line BL1 would not decrease to a critical voltage value that triggers the latch-up effect, thereby effectively mitigating the latch-up effect, reducing the risk of burning out the memory, and improving the reliability of the memory.

In some examples, in a case where the first word line WL1 is discharged in steps, since a fall rate of the voltage of the first word line WL1 changes from the starting point of time (for example, the second point of time t2) of the subsequent step of discharging, the voltage of the first bit line BL1 may also first decrease and then increase from the second point of time t2. Similarly, since the voltage drop of the first bit line BL1 occurs within a shorter time period after the second point of time t2, the overall trend of the voltage of the first bit line BL1 is upward from the second point of time t2 to the third point of time tb. At respective steps of discharging of the first word line WL1, rise rates of a voltage of the first bit line BL1 differ from each other.

In other examples, the charging voltage is provided to the first bit line BL1 during a discharging phase, such as from a certain point of time later than the first point of time t1. In other words, the starting point of time at which the charging voltage is provided to the first bit line BL1 may be later than the starting point of time at which the first word line WL1 is discharged. In this way, from the first point of time t1 to the starting point of time at which the charging voltage is provided to the first bit line BL1, the voltage of the first bit line BL1 continues to decrease. It can be ensured that the voltage of the first bit line BL1 would not drop to the critical voltage value that triggers the latch-up effect by reasonably setting the starting point of time at which the charging voltage is provided to the first bit line BL1.

In some examples, after the programming phase (e.g., in the discharging phase), the second bit line BL2 may be controlled to be in a floating state. For example, with reference to FIG. 3, the second bit line BL2 may be coupled with the page buffer 132, and the charging path is controlled to be disconnected from the second bit line BL2 in response to the control signal from the logic control circuit 135, so that the second bit line BL2 is in the floating state. Under the coupling effect with the first word line WL1, the voltage of the second bit line BL2 continues to decrease. Since the voltage of the second bit line BL2 (e.g., the bit-line inhibit voltage V_{dd}) is high at the end of the programming phase (e.g., the first point of time t1), the voltage of the second bit line BL2 would not decrease to a critical voltage value that triggers the latch-up effect, thereby effectively mitigating the latch-up effect, reducing the risk of burning out the memory, and improving the reliability of the memory.

In some examples, in a case where the first word line WL1 is discharged in steps, similarly, since the fall rate of the voltage of the first word line WL1 changes from the starting point of time (for example, the second point of time t2) of the subsequent step of discharging, the fall rate of the voltage of the second bit line BL2 after the second point of time t2 is different from the fall rate of the voltage of the second bit line BL2 from the first point of time t1 to the second point of time t2.

In some examples, as shown in FIG. 8, after the programming phase (e.g., in the discharging phase), a charging voltage may be provided to a first set of third bit lines (e.g., third bit line BL3-1) among the plurality of third bit lines and a second set of third bit lines (e.g., third bit line BL3-2) among the plurality of third bit lines are controlled to be in a floating state. A bit-line intermediate voltage V_{3bl} provided to the first set of third bit lines (for example, the third bit line BL3-1) is less than a preset threshold, and a bit-line intermediate voltage V_{4bl} provided to the second set of third bit lines (for example, the third bit line BL3-2) is greater than the preset threshold.

For example, with reference to FIG. 3, the first set of third bit lines (e.g., third bit line BL3-1) may be coupled with the page buffer 132, and a charging path is controlled to be connected with the first set of third bit lines (e.g., third bit line BL3-1) in response to a control signal from the logic control circuit 135 to provide a charging voltage to the first set of third bit lines (e.g., third bit line BL3-1). As another example, the second set of third bit lines (e.g., third bit line BL3-2) may be coupled with the page buffer 132, and a charging path is controlled to be connected with the second set of third bit lines (e.g., third bit line BL3-2) in response to a control signal from the logic control circuit 135 to cause the second set of third bit lines (e.g., third bit line BL3-2) to be in the floating state.

In the above examples, under the action of the charging voltage, the first set of third bit lines (e.g., the third bit line BL3-1) will not further decrease (e.g., can maintained at the charging voltage) to a critical voltage value that triggers the latch-up effect, thereby effectively mitigating the latch-up effect, reducing the risk of burning out the memory, and improving the reliability of the memory. In addition, under the coupling effect with the first word line WL1, the voltage of the second set of third bit lines (e.g., the third bit line BL3-2) will continue to decrease, since the voltage of the second set of third bit lines (e.g., the third bit line BL3-2) is higher (e.g., the bit-line intermediate voltage V_{4bl} is greater than the preset threshold) at the end of the programming phase (e.g., at the first point of time t1), and the voltage of the second set of third bit lines (e.g., the third bit line BL3-2) will not decrease to a critical voltage value that triggers the latch-up effect, thereby effectively mitigating the latch-up effect, reducing the risk of burning out the memory, and improving the reliability of the memory.

In some examples, during the discharging phase, a charging voltage may be provided to a first set of third bit lines (e.g., third bit line BL3-1) among the plurality of third bit lines from a first point of time t1. In some other examples, during the discharging phase, a charging voltage may be provided to the first set of third bit lines (e.g., third bit line BL3-1) from a certain point of time later than the first point of time t1, which is not limited in the present disclosure.

It should be noted that, in the above description, the first set of third bit lines and the second set of third bit lines are merely examples, and when the number of third bit lines with different bit-line intermediate voltages is greater than 2, the respective numbers of the third bit lines in the first set and the second set may also depend on the voltage values of the bit-line intermediate voltages, and the specific respective numbers of the third bit lines in the first set and the second set are not limited in the present disclosure.

In some examples, as shown in FIG. 10, the number of page buffers 132 may correspond to the number of bit lines 116. For example, each bit line 116 (e.g., first bit line BL1, second bit line BL2, third bit lines BL3-1 and BL3-2) may be coupled with one page buffer 132. The page buffer 132 may comprise a clamp transistor Tc. A first terminal of the clamp transistor Tc is coupled with each bit line 116 (e.g., the first bit line BL1, the second bit line BL2, the third bit lines BL3-1 and BL3-2), and a second terminal of the clamp transistor Tc is coupled with the power supply terminal 139. In other words, each bit line 116 (e.g., the first bit line BL1, the second bit line BL2, the third bit lines BL3-1 and BL3-2) is coupled with the power supply terminal 139 through one clamp transistor Tc, respectively. The power supply terminal 139 is configured to provide a power supply voltage V_{dd}.

In some examples, the clamp transistor Tc may comprise an NMOS transistor. For example, the first terminal of the clamp transistor Tc may be the source terminal, and the second terminal of the clamp transistor Tc may be the drain terminal. In other examples, the clamp transistor Tc may also comprise a PMOS transistor.

In some examples, in the process of providing the charging voltage to the first bit line BL1, a bias voltage V_{bias} may be provided to control terminals (e.g., gate) of a plurality of clamp transistors Tc, so that clamp transistors Tc among the plurality of clamp transistors Tc coupled with the first bit line BL1 and the first set of third bit lines (e.g., the third bit line BL3-1) are in a turn-on state, and clamp transistors Tc among the plurality of clamp transistors Tc coupled with the second bit line BL2 and the second set of third bit lines (e.g., the third bit line BL3-2) are in a turn-off state.

Taking the clamp transistor Tc being an NMOS transistor as an example, for example, the voltage value of the bias voltage V_{bias} may be the sum of the preset threshold and the threshold voltage of the clamp transistor Tc. At the starting point of time (e.g., the first point of time t1) at which the charging voltage is provided to the first bit line BL1, the voltage of the first bit line BL1 has a smaller value (e.g., the ground voltage Vₛₛ). In response to receiving the bias voltage V_{bias} at the control terminal (e.g., gate) of the clamp transistor Tc coupled with the first bit line BL1, the clamp transistor Tc coupled with the first bit line BL1 may be in the turn-on state, the first bit line BL1 is connected with the power supply terminal 139, and the power supply terminal 139 provides the charging voltage to the first bit line BL1.

In the process of providing the charging voltage to the first bit line BL1, in response to receiving the bias voltage V_{bias} at the control terminal (e.g., the gate) of the clamp transistor Tc coupled with the first set of third bit lines (e.g., the third bit line BL3-1), since the voltage of the first set of third bit lines (e.g., third bit line BL3-1) is less than the preset threshold, the clamp transistor Tc coupled with the first set of third bit lines (e.g., the third bit line BL3-1) may be in the turn-on state, the first set of third bit lines (e.g., the third bit line BL3-1) are connected with the power supply terminal 139, and the power supply terminal 139 provides the charging voltage to the first set of third bit lines (e.g., the third bit line BL3-1).

In the process of providing the charging voltage to the first bit line BL1, in response to receiving the bias voltage V_{bias} at the control terminal (e.g., the gate) of the clamp transistor Tc coupled with the second bit line BL2, since the voltage of the second bit line BL2 has a larger value (e.g., the power supply voltage V_{dd}), the voltage of the second bit line BL2 drops but will not turn on the clamp transistor Tc coupled thereto, thus the clamp transistor Tc is in the turn-off state. Thus, the second bit line BLb is disconnected from the power supply terminal 139 and is in a floating state.

In the process of providing the charging voltage to the first bit line BL1, in response to receiving the bias voltage V_{bias} at the control terminal (e.g., the gate) of the clamp transistor Tc coupled with the second set of third bit lines (e.g., third bit line BL3-2), since the voltage of the second set of third bit lines (e.g., the third bit line BL3-2) is greater than the preset threshold, the voltage of the second set of third bit lines (e.g., the third bit line BL3-2) drops but may not turn on the clamp transistor Tc coupled thereto, thus the clamp transistor Tc is in the turn-off state. As such, the second set of third bit lines (e.g., third bit line BL3-2) are disconnected from the power supply terminal 139 and are in a floating state.

Although example structure of memory and example operations of a method for programming memory are described herein, it is to be understood that one or more features may be omitted, replaced, or added from the structure or the method for programming the memory. Further, the illustrated content is for illustrative purposes only.

It should be understood that the operations may be reordered, added or deleted using the various forms of flows shown above, as long as the results expected by the technical solutions disclosed in the present disclosure can be achieved, which is not limited herein.

The above description is only an example of the present disclosure and an explanation of the technical principles applied. It should be understood by those skilled in the art that the protection scope involved in the present disclosure is not limited to the technical solutions of the specific combination of the above technical features, and should also cover other technical solutions formed by any combination of the above technical features or their equivalent features without departing from the technical concept, for example, the technical solutions formed by replacing the above features with the technical features with similar functions disclosed in the present disclosure (but not limited thereto).

What is claimed is:

1. A memory, comprising:
a memory cell array comprising a first memory cell coupled with a first bit line and a first word line; and
a peripheral circuit coupled with the memory cell array and configured to:
provide a word-line programming voltage to the first word line and a bit-line programming voltage to the first bit line during a programming phase;
discharge the first word line from the word-line programming voltage after the programming phase; and
provide a charging voltage to the first bit line in the process of discharging the first word line from the word-line programming voltage.

2. The memory of claim 1, wherein the peripheral circuit is further configured to:
discharge the first word line from the word-line programming voltage from a first point of time; and
provide the charging voltage to the first bit line from the first point of time.

3. The memory of claim 1, wherein the memory cell array further comprises a second memory cell coupled with a second bit line and the first word line,
wherein the peripheral circuit is further configured to:
provide a bit-line inhibit voltage to the second bit line during the programming phase, wherein the bit-line inhibit voltage is greater than the bit-line programming voltage; and
control the second bit line to be in a floating state after the programming phase.

4. The memory of claim 3, wherein the memory cell array further comprises a plurality of third memory cells coupled with a plurality of third bit lines and the first word line,
wherein the peripheral circuit is further configured to:
provide a plurality of bit-line intermediate voltages to the plurality of third bit lines during the programming phase, wherein the plurality of bit-line intermediate voltages are greater than the bit-line programming voltage and less than the bit-line inhibit voltage, and the plurality of bit-line intermediate voltages are different from each other; and
provide the charging voltage to a first set of third bit lines among the plurality of third bit lines and control a second set of third bit lines among the plurality of third bit lines to be in the floating state after the programming phase, wherein the bit-line intermediate voltages provided to the first set of third bit lines are less than a preset threshold, and the bit-line intermediate voltages provided to the second set of third bit lines are greater than the preset threshold.

5. The memory of claim 4, wherein the first bit line, the second bit line, and the third bit lines are respectively coupled with a power supply terminal through a plurality of clamp transistors, and the peripheral circuit is further configured to:
in the process of providing the charging voltage to the first bit line, provide a bias voltage to control terminals of the plurality of clamp transistors, so that the clamp transistors among the plurality of clamp transistors coupled with the first bit line and the first set of third bit lines are in a turn-on state, and the clamp transistors among the plurality of clamp transistors coupled with the second bit line and the second set of third bit lines are in a turn-off state.

6. The memory of claim 5, wherein the clamp transistors comprise a NMOS transistor.

7. The memory of claim 5, wherein a voltage value of the bias voltage is a sum of the preset threshold and a threshold voltage of the clamp transistors.

8. The memory of claim 3, wherein the peripheral circuit is further configured to:
discharge the first word line from the word-line programming voltage in steps.

9. The memory of claim 8, wherein at respective steps in the process of discharging the first word line, rise rates of a voltage of the first bit line differ from each other, and fall rates of a voltage of the second bit line differ from each other.

10. The memory of claim 1, wherein the memory cell array further comprises a plurality of second word lines, and the peripheral circuit is further configured to:
provide a pass voltage to the second word lines during the programming phase; and
discharge the second word lines from the pass voltage after the programming phase, wherein the pass voltage is less than the word-line programming voltage.

11. The memory of claim 1, wherein the bit-line programming voltage comprises a ground voltage.

12. A memory system, comprising:
a memory, comprising:
a memory cell array comprising a first memory cell coupled with a first bit line and a first word line; and
a peripheral circuit coupled with the memory cell array and configured to:
provide a word-line programming voltage to the first word line and a bit-line programming voltage to the first bit line during a programming phase;
discharge the first word line from the word-line programming voltage after the programming phase; and
provide a charging voltage to the first bit line in the process of discharging the first word line from the word-line programming voltage; and
a controller coupled with the memory and configured to control the memory.

13. An operating method for a memory, wherein the memory comprises a first memory cell coupled with a first bit line and a first word line, and the operating method comprises:
providing a word-line programming voltage to the first word line and a bit-line programming voltage to the first bit line during a programming phase;
discharging the first word line from the word-line programming voltage after the programming phase; and
providing a charging voltage to the first bit line in the process of discharging the first word line from the word-line programming voltage.

14. The operating method of claim 13, wherein:
discharging the first word line from the word-line programming voltage comprises:
discharging the first word line from the word-line programming voltage from a first point of time, and
providing the charging voltage to the first bit line comprises:
providing the charging voltage to the first bit line from the first point of time.

15. The operating method of claim 14, wherein the memory further comprises a second memory cell coupled with a second bit line and the first word line, and the operating method further comprises:
providing a bit-line inhibit voltage to the second bit line during the programming phase, wherein the bit-line inhibit voltage is greater than the bit-line programming voltage; and
controlling the second bit line to be in a floating state after the programming phase.

16. The operating method of claim 15, wherein the memory further comprises a plurality of third memory cells coupled with a plurality of third bit lines and the first word line, and the operating method further comprises:
providing a plurality of bit-line intermediate voltages to the plurality of third bit lines during the programming phase, wherein the plurality of bit-line intermediate voltages are greater than the bit-line programming voltage and less than the bit-line inhibit voltage, and the plurality of bit-line intermediate voltages are different from each other; and
providing the charging voltage to a first set of third bit lines among the plurality of third bit lines and controlling a second set of third bit lines among the plurality of third bit lines to be in the floating state after the programming phase, wherein the bit-line intermediate voltages provided to the first set of third bit lines are less than a preset threshold, and the bit-line intermediate voltages provided to the second set of third bit lines are greater than the preset threshold.

17. The operating method of claim 16, wherein the first bit line, the second bit line, and the third bit lines are respectively coupled with a power supply terminal through a plurality of clamp transistors, and the operating method further comprises:
in the process of providing the charging voltage to the first bit line, providing a bias voltage to control terminals of the plurality of clamp transistors, so that the clamp transistors among the plurality of clamp transistors coupled with the first bit line and the first set of third bit lines are in a turn-on state, and the clamp transistors among the plurality of clamp transistors coupled with the second bit line and the second set of third bit lines are in a turn-off state.

18. The operating method of claim 17, wherein the clamp transistors comprise a NMOS transistor.

19. The operating method of claim 17, wherein a voltage value of the bias voltage is a sum of the preset threshold and a threshold voltage of the clamp transistors.

20. The operating method of claim 15, wherein discharging the first word line from the word-line programming voltage comprises:
discharging the first word line from the word-line programming voltage in steps.
